(19) United States
(12) Patent Application Publication
(10) Pub. No.: US 2006/0127577 A1
(43) Pub. Date: Jun. 15, 2006

(54) Niobium-based compositions and coatings, niobium oxides and their alloys applied by thermal spraying and their use as an anticorrosive

(76) Inventors: Luiz Roberto Martins Miranda, Petropolis (BR); Ladimir Jose Carvalho, Rio de Janeiro (BR); Antonio Carlos Goncalves Pereira, Petropolis (BR)

Correspondence Address: Luiz Roberto Martins Miranda Fildes & Outland, 20916 Mack Avenue, Suite 2, Grosse Pointe Woods, MI, 48236, US

(21) Appl. No.: 10/525,366

(22) PCT Filed: Nov. 13, 2002
(86) PCT No.: PCT/BR02/00152

§ 371 Date: Feb. 23, 2005

(30) Foreign Application Priority Data
Sep. 6, 2002 (BR) PI 0203534-0

(51) Int. Cl. C23C 16/00

(52) U.S. Cl. 427/250

(57) ABSTRACT

The novelty proposed herein describes the application of niobium-based compositions and coatings, niobium oxides and their alloys capable of associations with other oxides and alloys by means of the thermal spraying technique for the purpose of an anticorrosive protection in highly corrosive environments, mainly those which present high temperatures, show presence of gases such as H₂S, SO₂, CO₂, as well as organic and inorganic acids, commonly found in industrial centers.

### THECHNICAL FIELD

This invention refers to the application of niobium-based compositions and coatings, niobum oxides and their alloys capable of association with other oxides and alloys by means of the thermal spraying technique for the purpose of an anticorrosive protection in highly corrosive environments, mainly those wich present high temperatures, show presence of gases such as H₂S, SO₂, CO₂ as well as organic and inorganic acids.

### PRIOR TECHNIQUES

The Brazilian Patent Application n^{o} PI 0102414-0 refers to niobium-based compositions and coatings, niobium oxides and their possible associations with other oxides and their use by means of common painting techniques and not by electrodeposition through molten salts or equivalents thereof used in electroplating, it being understood that same is proposed to neutralize the highly corrosive effect of naphthenic acids and sulphur components, which very quickly destroy carbon steel and special alloys such as stainless steel of virtually all chromium alloys and nickel alloys families, and for use not only as a coating in petroleum refining units, but also in industrial units which present similar problems.

### SUMMARY OF THE INVENTION

In its most general aspect, this invention proposes the use of niobium, niobium oxides, niobium alloys and associations thereof with other metals, alloys or oxides as an anticorrosive coating applied by a thermal spraying technique over carbon steel surfaces and other metallic materials of current use in industrial centers.

### DETAILED DESCRIPTION OF THE INVENTION

This invention refers more particularly to formulations comprising the use of niobium and oxides and alloys thereof such as Ni—Nb, Fe—Nb, HNb, among others by granulometric classification that allows their application by a thermal spraying equipment.

The components referred to above obey the following characteristics:
Boiling point: a maximum of 2000° C.
Density: 4.47-8.0 g/cm³
% niobium oxide: 99.4
Sulphur ppm: 10
Fe ppm: 229
Pb ppm: <1
Granulometry: [−180 to 45 μm]

Thermal spraying is a set of coating process in which metallic or non-metallic materials in the form of a powder or a wire are molten in the nozzle of appropriate guns, and then projected under pressure towards the surface to be coated. Due to the high pressure, these molten materials come out from the guns as microdroplets which, upon approaching, the substrate become grouped and then are deposited in the form of “flakes”, sometimes also called “pancakes”. From this moment on, there are depositions of successive layers and thus a thermo-sprayed characteristic coating provided with superposed “pancakes”. These flakes are affixed to the substrate by mechanical anchoring processes, and therefore there is the need of a prior preparation of the substrate so as to enable required anchoring conditions.

The surface to be sprayed thermically must be previously cleaned. The cleaning process consists of the following phases:

1—Surface Pre-Cleaning.

It consists of the removal of sludge, corrosion products, coatings residues, insoluble incrustations, scales and gross particulates through mechanical processes (hydro-jetting or abrasive blasting), chemical processes (degreasing, acid cleaning) or thermal processes (burning, direct flame, reducing atmosphere).

2—Final Cleaning.

It consists of the preparation of the surface by the blasting process so as to eliminate products that prevent the contact between the coating and the substrate. The surface must achieve a Sa3 cleaning quality and a given roughness, that is surface conditions allowing for the adherence of the coating to the substrate.

3—Preheating.

Preheating during its pre-cleaning is, in fact, a cleaning by the action of the flame and its purpose is to provide the burning and volatization of greases, oils and humidity retained at the metal substrate in the event of failure of the other cleaning methods. It can also be used after the final cleaning so as to reduce all residual tensions (which have an influence upon the adhesion and cohesion of the layer) and to remove any residual humidity. The preheating temperature values depend further upon the material of the layer, of the type of the substrate, and of its physical properties.

The coating process refers to the exemple 1 which consists of the application of niobium oxide by thermal spraying to the flame.

### EXAMPLE 1

### Application of a Niobium Oxide Layer Over a 3 mm Thick Carbon Steel Plate

Initially, the surface is blasted, to get it cleaned and to obtain the desired roughness, with white aluminium oxide granulometry 30 alundum 38 A; to obtain the Sa3 cleaning degree by comparison with all surface quality standards as published by NACE RM 01/70 rule. Then the surface must be heated for removal of humidity; to control the heating so that the temperature is not in excess of 150° C.; in the sequence, to apply a pre-layer of Ni, Al and Mo (bonder) agglomerate with a minimum thickness of 10 μm, for the purpose of providing the adherence of the coating. An alternative for the pre-layer of adherence is the 40A1-60Nb agglomerate. Finally, to fill up the equipment with niobium oxide with a granulometry between −180 to 45 μm, to adjust the parameters and carry out the application.

Parameters for application of niobium oxide and niobium alloys:
Oxygen pressure: 2.0 to 4.0 kg/cm²
Acetylene pressure 0.5 to 1.0 kg/cm²
Deposition rate regulation^{(*)}: 5-15
   ^{(*)} Depending on the thickness of the layer to be applied, the deposition rate must be altered.

Upon application the deposited layer must have the following characteristics:

A—Thickness

Verify the thickness using a thickness meter specific for measuring non magnetic layers over magnetic substrates. For a primer the thickness of the layer applied must be in the range of 100 μm.B

B—Adherence

Glue to the applied layer with an adhesive a peg of 25.4 mm in diameter which upon curing is tensioned in a tension machine. The adherence value must be between 10 and 40 Mpa.

C—Electrode Power

Up to 100° C. the electrochemical power measured in relation to the saturated calomel over a carbon steel substrate must show the value of −600+/=50 mV_{ecs}.

D—Instilling of HCl of P.A. Purity

It must not show deteriorations in the coating and show yellow oxidation characteristic of the oxide reaction.

The above defined parameters should not be deemed to be restricted to the scope of this invention, as other forms of application by thermal spraying can be used.

1. “Niobium-Based Compositions and Coatings, Niobum Oxides and Their Alloys Applied by Thermal Spraying” characterized by applying niobium, its oxides and alloys such as Ni—Nb, Fe—Nb, HNb, among others, obeying the following characteristics, boiling point up to a maximum of 2000° C., density of 4.47 to 8.0 g/cm³, niobium oxide 99.4%, sulphur ppm at 10, Fe ppm at 229, Pb ppm at <1 and granulometry of [−180 to 45 μm] by thermal spraying.

2. “Niobium-Based Compositions and Coatings, Niobium Oxides and Their Alloys Applied by Thermal Spraying” according to claim 1, characterized by using, more specifically in case of an adherence pre-layer, the agglomerate of 40 Al-60 Nb with niobium oxide with a granulometry between −180 to 45 μm.

3. “Niobium-Based Compositions and Coatings, Niobium Oxides and Their Alloys Applied by Thermal Spraying”, according to claim 1, characterized by obeying the following parameters for application of the niobium oxide and niobium alloys, oxygen pressure of 2.0 to 4.0 kg/cm³, acetylene pressure of 0.5 to 1.0 kg/cm², deposition rate regulation 5-15.

4. “Use as an anticorrosive” as described in Me preceding claim 1, characterized by using niobium and niobium alloys such as Ni—Nb, Fe—Nb, HNb among others, as an anticorrosive coating.

5. “Niobium-Based Compositions and Coatings, Niobium Oxides and Their Alloys Applied by Thermal Spraying”, according to claim 2, characterized by obeying the following parameters for application of the niobium oxide and niobium alloys, oxygen pressure of 2.0 to 4.0 kg/cm³, acetylene pressure of 0.5 to 1.0 kg/cm², deposition rate regulation 5-15.

6. “Use as an anticorrosive” as described in claim 2, characterized by using niobium and niobium alloys such as Ni—Nb, Fe—Nb, HNb among others, as an anticorrosive coating.

7. “Use as an anticorrosive” as described claim in 3, characterized by using niobium and niobium alloys such as Ni—Nb, Fe—Nb, HNb among others, as an anticorrosive coating.
